(19) United States
(12) Patent Application Publication
(10) Pub. No.: US 2026/0076143 A1
(43) Pub. Date: Mar. 12, 2026

(54) TRAY

(71) Applicant: SUZHOU REMUS PRECISION TECHNOLOGY CO., LTD., Suzhou City (CN)

(72) Inventors: Rongzhang ZHANG, Suzhou City (CN); Shourong WANG, Suzhou City (CN)

(21) Appl. No.: 19/389,822

(22) Filed: Nov. 14, 2025

Related U.S. Application Data
(63) Continuation of application No. PCT/CN2024/093650, filed on May 16, 2024.

(30) Foreign Application Priority Data
May 16, 2023 (CN) 202310548027.3

(51) Int. Cl. H01L 21/673; B29C 45/16

(52) U.S. Cl. CPC H10P 72/165; B29C 45/164

(57) ABSTRACT

Discloses is a tray including a baseplate (1), wherein a positioning unit (3) for supporting a product is arranged on the baseplate (1), the positioning unit (3) includes a plurality of positioning assemblies (30) distributed on an upper surface of the baseplate (1) and enclosing a placement area (300) therebetween; a first groove (13) is arranged on the upper surface of the baseplate (1), and a through hole (130) is opened within the first groove (13); each of the plurality of positioning assemblies (30) includes a positioning body (301) and a covering body (302), the positioning body (301) is arranged within the first groove (13), and the covering body (302) covers the first groove (13) and a surface of the positioning body (301), and the covering body (302) passes through the through hole (130) and covers a part of a lower surface of the baseplate (1).

### TECHNICAL FIELD

The present disclosure belongs to the field of electronic manufacturing technology, and specifically relates to a tray.

### BACKGROUND

Chips, as a type of electronic components, especially high-end chips, have high value but are prone to damage or failure, which have very high requirements for their package and protection. As an indispensable carrier in the process of packaging, testing, and mounting chips, a tray accompanies the entire manufacturing process of a chip.

Currently, a common tray is manufactured by using a monochrome injection molding process or an injection molding and overmolding process. Wherein, the monochrome injection molding process uses a mold with an injection molding cavity, and only uses single kind of hard plastic material for injection molding, an injection molded tray obtained after injection molding has good strength but its material is hard, and for a chip of large size and large weight, the injection molded tray is prone to damaging the chip, and the injection molding material are prone to shedding and contaminating the chip, resulting in quality problems. For the tray made by the injection molding and overmolding process, its base is made of hard plastic material and formed by monochrome injection molding, and both on the upper and lower surfaces of the base are formed with positioning protrusions for positioning the chip, then, through double-sided overmolding process, soft plastic is used to coat the positioning protrusions on the upper and lower surfaces of the base, the hard plastic has good strength, which can ensure the strength of the tray, while the soft plastic has lower hardness, which can provide certain cushioning force for the chip, reduce stress, and avoid damage to the chip. However, when using soft plastic for coating, it is needed to cover all the positioning protrusions on the upper and lower surfaces of the base, resulting in material waste and increased production costs, and the injection molding and overmolding process requires two sets of molds for processing, which takes a long molding time and is difficult to control the size during molding.

### SUMMARY

An object of the present disclosure is to provide a tray with high strength, stable structure, and effective protection for products, which can be applied to carry chips or other components during their packaging and transportation process to reduce damage caused by collisions.

An aspect of the present disclosure provides a tray, including a baseplate, a positioning unit for supporting a product is arranged on the baseplate, the positioning unit comprises a plurality of positioning assemblies distributed on an upper surface of the baseplate and enclosing a placement area therebetween; a first groove is arranged on the upper surface of the baseplate, and a through hole is opened within the first groove; each of the plurality of positioning assemblies comprises a positioning body and a covering body, the positioning body is arranged within the first groove, and the covering body covers the first groove and a surface of the positioning body, and the covering body passes through the through hole and covers a part of a lower surface of the baseplate.

Preferably, the baseplate and the positioning body are made of same material and are integrally formed; the baseplate and the covering body are integrally formed by double-shot molding, with easy size control, short molding time, simple process, and high connection strength between the baseplate and the covering body.

Preferably, the material of the baseplate is hard plastic, which includes MPPO, PAS, PPE, ABS, etc.; the material of the covering body is an elastic material, such as soft plastic, which includes TPU, TPE, silicone, etc. During injection molding, the hard and soft plastic can adsorb and melt with each other to a certain extent, generating adhesive force and further improving the connection strength between the baseplate and the covering body.

Preferably, a portion of the covering body covering a surface of the positioning body has a supporting surface, which can stably support the chip in a vertical direction.

Further preferably, the supporting surface extends in a horizontal direction, and a height level of the supporting surface is higher than that of the upper surface of the baseplate, and the periphery of the chip can be placed on the horizontal supporting surface to ensure the stability of the support.

Further preferably, the supporting surface slops downwards to the placement area, and compared to a horizontal supporting surface, the inclined supporting surface can minimize contact area with the welding spots of the chip and avoid damage.

Further preferably, the supporting surface on each positioning body is independently provided, such that the supporting surface on each positioning body can serve as a support, thereby forming multi-point support.

Further preferably, the supporting surfaces of two adjacent positioning bodies in two adjacent directions are connected in an L-shape, which can provide stable support for the corner position.

Preferably, a portion of the covering body covering the surface of the positioning body has a limiting surface extending in a vertical direction for limiting a displacement of the product in a horizontal direction.

Preferably, a height level of the covering body covering the first groove is lower than that of the upper surface of the baseplate.

Preferably, a portion of the covering body extending out from the through hole has a size larger than a size of the through hole, and forms an inversed buckle structure to further improve the stability of the connection and prevent the covering body from falling off.

Preferably, each of the plurality of positioning assemblies further comprises a connecting body arranged on the upper surface of the baseplate on a side of the positioning body, the connecting body and the placement area are respectively located on two sides of the positioning body, and the covering body covers between the connecting body and the positioning body. By providing the connecting body, the connection strength of the covering body is further improved.

Preferably, a second groove is further arranged within the first groove, and the through hole extends to the second groove. By providing the second groove, the contact area of the covering body is further increased, which further improve its connection strength.

Further preferably, at least part of a bottom surface of the first groove protrudes from a lower surface of the baseplate, ensuring the depth of the first groove and the second groove while preventing excessive thickness of the baseplate, achieving the goal of weight reduction.

Preferably, the plurality of positioning assemblies enclose the placement area in a square shape.

Preferably, a plurality of positioning bodies are arranged along a length direction of the first groove; a width of a top of each of the plurality of positioning bodies is less than a width of a bottom thereof.

Preferably, a plurality of through holes are arranged along a length direction of the first groove.

Further preferably, the number of through hole(s) is 1 to 4, which may be 1, 2, 3 or 4 as needed, and of course, may also be 5 or more.

Preferably, an upper supporting body is arranged on the upper surface of the baseplate, and when multiple trays are stacked, the upper supporting body of one tray located at a lower layer supports the lower surface of another tray located at an upper layer.

Preferably, a lower supporting body is arranged on the lower surface of the baseplate, and when multiple trays are stacked, the upper supporting body of one tray located at a lower layer supports the lower supporting body of another tray located at an upper layer. The upper supporting body and the lower supporting body not only serve as support during stacking, but also enhance the overall strength of the tray.

Preferably, a plurality of lightening holes penetrate through the baseplate are arranged on the baseplate.

Preferably, the tray further comprises a frame enclosing a perimeter of the baseplate.

Further preferably, the frame protrudes from both the upper surface and the lower surface of the baseplate, to form an enclosure around it; when multiple trays are stacked, the frames of two adjacent trays abut each other.

Preferably, the tray further comprises a reinforcing assembly comprising a reinforcing rib arranged between the baseplate and the frame, and providing the reinforcing rib can improve the overall strength of the tray and prevent the chip from being damaged by deformation when it is clamped.

Preferably, a plurality of positioning units are distributed along a length direction of the baseplate.

Further preferably, the number of positioning unit(s) is 1 to 8, more preferably 3 to 5.

Due to the use of the above technical solutions, the present disclosure has the following advantages over conventional art:

the present disclosure provides a covering body on the baseplate, the baseplate has good toughness, strength, and structural stability, and the covering body can provide sufficient cushion force for a chip, such that the tray has both high strength and good cushion performance, effectively improving the protective performance of the tray against the chip; the covering body and the baseplate have a strong connection force therebetween, are not easy to fall off, and the structural stability is good; the structure of the covering body is simple, with less material usage, which reduces production and processing costs, and the weight of the tray is relatively light, making it easy to pack and transport, and have good practicality.

### BRIEF DESCRIPTION OF THE DRAWINGS

FIG. 1 is a schematic top view of a tray in an embodiment;

FIG. 2 is a partially enlarged schematic diagram of Part A in FIG. 1;

FIG. 3 is a schematic cross-sectional view along Line B-B in FIG. 1;

FIG. 4 is a partially enlarged schematic diagram of Part C in FIG. 3;

FIG. 5 is a schematic bottom view of a tray in an embodiment;

FIG. 6 is a partially enlarged schematic diagram of Part D in FIG. 5;

FIG. 7 is a schematic top view of a tray in an embodiment, wherein a covering body is not shown;

FIG. 8 is a partially enlarged schematic diagram of Part E in FIG. 7;

FIG. 9 is a schematic cross-sectional view along Line F-F in FIG. 7;

FIG. 10 is a partially enlarged schematic diagram of Part G in FIG. 9;

FIG. 11 is a schematic bottom view of a tray in an embodiment, wherein a covering body is not shown;

FIG. 12 is a partially enlarged schematic diagram of Part H in FIG. 11;

FIG. 13 is a schematic top view of a tray of another structure in an embodiment;

FIG. 14 is a schematic diagram of an example of a supporting surface in an embodiment;

FIG. 15 is a schematic diagram of another example of a supporting surface in an embodiment;

wherein,
1—baseplate; 10—lightening hole; 11—upper supporting body; 12—lower supporting body; 13—first groove; 130—through hole; 14—second groove;
2—frame;
3—positioning unit; 30—positioning assembly; 300—placement area; 301—positioning body; 302—covering body; 3021—supporting surface; 3022—limiting surface; 3023—guiding surface; 303—connecting body;
4—reinforcing assembly; 40—reinforcing rib.

### DETAILED DESCRIPTION OF EXEMPLARY EMBODIMENTS

The technical solutions of the present disclosure will be described clearly and completely below in combination with the accompanying drawings. Apparently, the described embodiments are merely some of rather than all of the embodiments of the present disclosure. All other embodiments obtained by those of ordinary skill in the art without creative efforts based on the embodiments of the present disclosure shall fall within the protective scope of the present disclosure.

In the description of the present disclosure, it should be noted that the orientations or positional relationships indicated by the terms “center”, “upper”, “lower”, “left”, “right”, “vertical”, “horizontal”, “inner”, “outer”, etc. are based on those shown in the accompanying drawings, are only for the convenience of describing the present disclosure and simplifying the description, rather than indicating or implying that the indicated device(s) or element(s) must have a specific orientation, be constructed and operated in a specific orientation, and therefore should not be construed as a limitation of the present disclosure. Furthermore, the terms “first”, “second” and “third” are used for descriptive purposes only and should not be construed to indicate or imply relative importance.

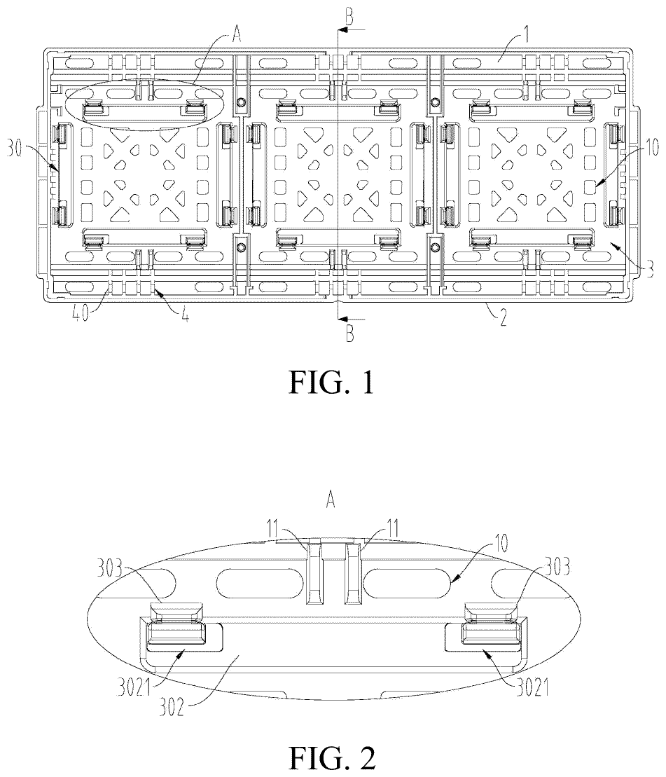

A tray can be specifically used to load electronic components, such as chips. As shown in FIG. 1 and FIG. 5, the tray comprises a baseplate 1, a frame 2, and a positioning unit 3. The frame 2 encloses the perimeter of the baseplate 1, and the positioning unit 3 is used to support a chip and arranged on the baseplate 1. The positioning unit 3 comprises a plurality of positioning assemblies 30 enclosing a placement area 300 therebetween for placing the chip.

The respective components and their connection relationships will be described in detail as below.

As shown in FIG. 1 and FIG. 5, the baseplate 1 is rectangular, such as square, oblong, etc., in this embodiment, the baseplate 1 is oblong. The baseplate 1 is provided with a lightening hole 10 penetrating through an upper surface and a lower surface of the baseplate 1. There can be a plurality of lightening holes 10, multiple lightening holes 10 may be provided on the baseplate 1 located within the placement area 300, and multiple lightening holes 10 may be provided on the baseplate 1 located between the positioning assemblies 30 and the frame 2, to reduce the weight of the tray.

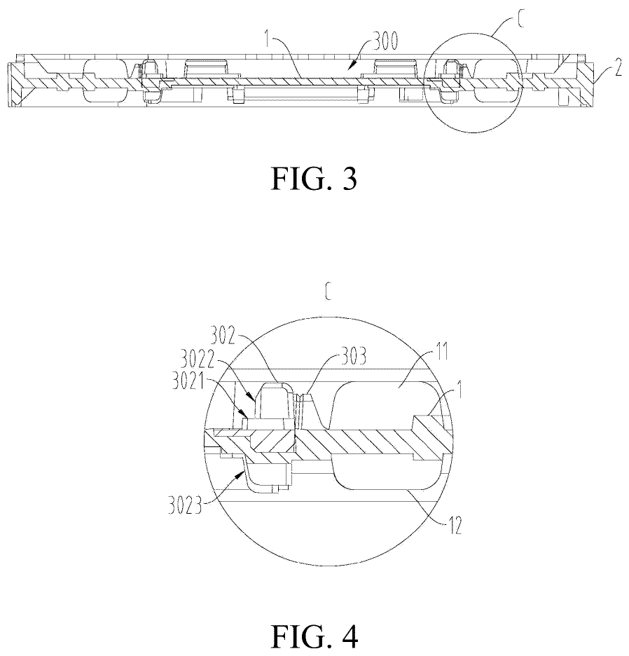

As shown in FIG. 1 and FIG. 3, the frame 2 surrounds the perimeter of the baseplate 1, and the frame 2 protrudes from both the upper surface and the lower surface of the baseplate 1, forming an enclosure around it. In addition, four corners of the frame 2 are rounded. When a plurality of trays are stacked, frames 2 of two adjacent trays abut each other.

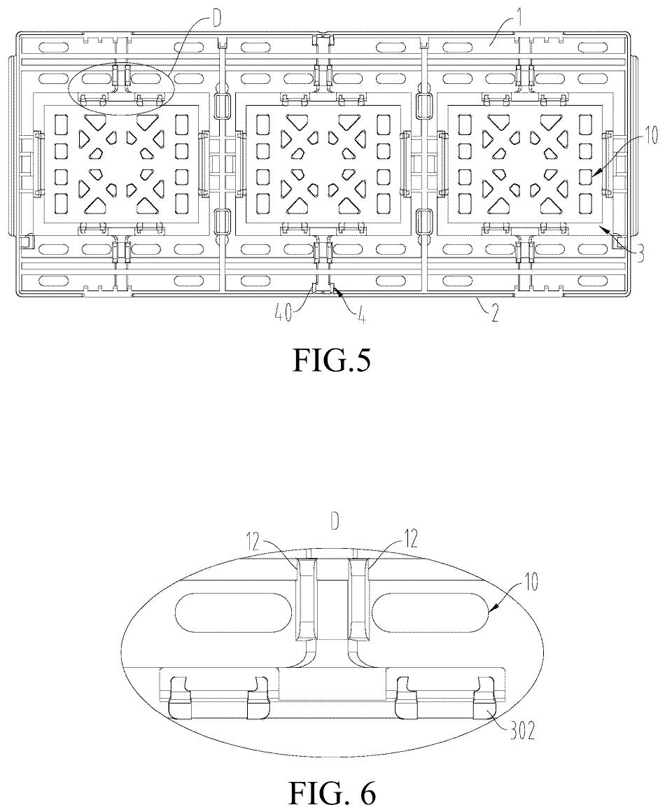

As shown in FIG. 2 and FIG. 6, the upper surface of the baseplate 1 is provided with an upper supporting body 11, and/or the lower surface of the baseplate 1 is provided with a lower supporting body 12. In this embodiment, the upper surface and the lower surface of the baseplate 1 are respectively provided with an upper supporting body 11 and a lower supporting body 12. When a plurality of trays are stacked, the upper supporting body 11 of the tray located at a lower layer supports on the lower supporting body 12 of a tray located at an upper layer. The upper supporting body 11 and the lower supporting body 12 not only serve as supports during stacking, but also enhance the overall strength of the tray, preventing the upper tray from deforming and pressing onto the chips placed on the lower tray.

As shown in FIG. 1 and FIG. 5, a plurality of upper supporting bodies 11 may be arranged, and the plurality of upper supporting bodies 11 are distributed on the upper surface of the baseplate 1. Specifically, two upper supporting bodies 11 distributed along the length direction of the baseplate 1 form one pair, multiple pairs of upper supporting bodies 11 are evenly distributed along the length direction of the baseplate 1, and multiple pairs of upper supporting bodies 11 are symmetrically arranged along the width direction of the baseplate 1. A plurality of lower supporting bodies 12 are also provided, and the plurality of lower supporting bodies 12 are distributed on the lower surface of the baseplate 1, and the specific positions and number of the lower supporting bodies 12 correspond to those of the upper supporting bodies 11, and will not be repeated here. The shapes of the upper supporting bodies 11 and the lower supporting bodies 12 can be strip-shaped, columnar, etc.

As shown in FIG. 1 and FIG. 5, a reinforcing assembly 4 is further arranged between the baseplate 1 and the frame 2, and the reinforcing assembly 4 is used to improve the packaging capability of the tray. Specifically, a plurality of reinforcing assemblies 4 are arranged, and the plurality of reinforcing assemblies 4 are distributed around the perimeter of the frame 2, that is to say, there are a plurality of reinforcing assemblies 4 provided between the upper surface of baseplate 1 and the frame 2, and there are also a plurality of reinforcing assemblies 4 arranged between the lower surface of the baseplate 1 and the frame 2. The reinforcing assembly 4 specifically adopts for example a reinforcing rib 40, which is arranged between the baseplate 1 and the frame 2, and a plurality of reinforcing ribs 40 may be arranged, and the plurality of reinforcing ribs 40 are distributed in the horizontal direction. By providing the reinforcing assembly 4, the packaging capacity of the tray can be improved to prevent deformation such as arching and indentation when the tray is clamped by a robotic arm, which may cause chip damage.

As shown in FIG. 1 and FIG. 5, a plurality of positioning units 3 are arranged, and the plurality of positioning units 3 are distributed along the length direction of the baseplate 1, and the specific number of positioning units 3 may be 1 to 8, preferably 3 to 5. In this embodiment, the FIGs shown three positioning units 3 as an example, the three positioning units 3 are distributed along the length direction of the baseplate 1, and two adjacent positioning units 3 are separated from each other by a structure protruding from the baseplate 1.

The plurality of positioning assemblies 30 are distributed on the upper surface of the baseplate 1, and encloses the placement area 300 therebetween. In this embodiment, as shown in FIG. 1 and FIG. 5, there are four positioning assemblies 30, which enclose the placement area 300 in four directions, forming a square placement area 300 between the four positioning assemblies 30.

As shown in FIG. 3 and FIG. 4, the positioning assembly 30 comprises a positioning body 301, a covering body 302, and a connecting body 303, the positioning body 301 and the connecting body 303 are arranged on the upper surface of the baseplate 1, and the covering body 302 covers the positioning body 301 and is connected to the connecting body 303.

Specifically, as shown in FIG. 2 and FIG. 8, a first groove 13 is arranged on the upper surface of the baseplate 1, which is rectangular, such as square, oblong, etc. In this embodiment, four first grooves 13 are provided, and oblong in shape.

The positioning body 301 is arranged within the first groove 13, and extends along the thickness direction of the baseplate 1, the top of the positioning body 301 protrudes from the first groove 13, and the top width of the positioning body 301 is less than the bottom width thereof. There are a plurality of positioning bodies 301 distributed along the length direction of the first groove 13. In this embodiment, there are eight positioning bodies 301, and two positioning bodies 301 are arranged at two ends of the length direction of the first groove 13, respectively. Specifically, each positioning body 301 comprises a pair (two) of convex columns, with a gap between them, as shown in FIG. 8.

As shown in FIG. 8 and FIG. 12, a through hole 130 is arranged within the first groove 13, which penetrates the baseplate 1. Specifically, there are a plurality of through holes 130 distributed along the length direction of the first groove 13, and the specific number of the through holes 130 may be 1 to 4. In this embodiment, the through holes 130 are arranged within the first groove 13 between two positioning bodies 301. In the FIGs, there are four through holes 130 arranged within the first groove 13 at the position of the positioning assembly 30 arranged along the width direction of the baseplate 1, and the four through holes 130 are symmetrically arranged in pairs along the length direction of the first groove 13; there are two through holes 130 arranged within the first groove 13 at the position of the positioning assembly 30 arranged along the length direction of the baseplate 1, and the two through holes 130 are symmetrically arranged along the length direction of the first groove 13.

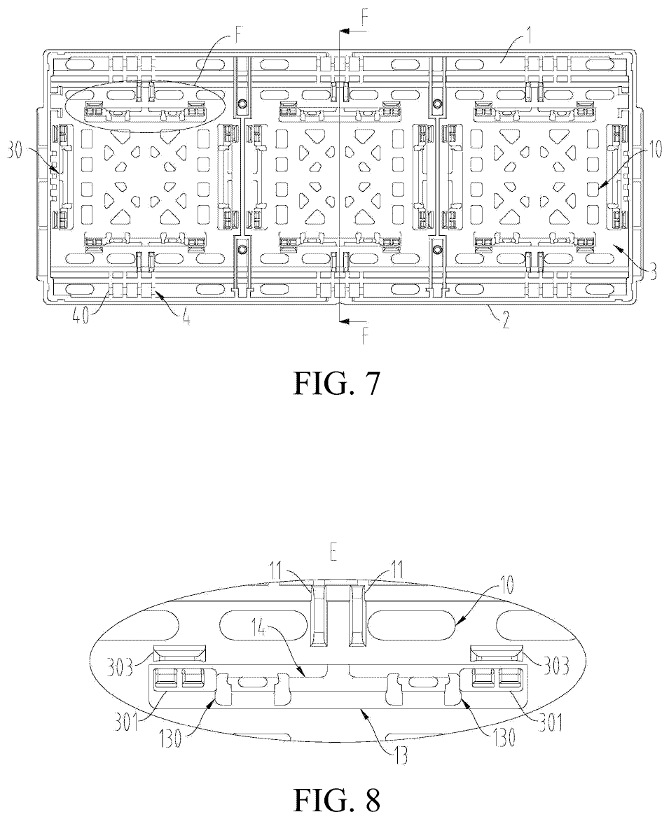

In addition, in some embodiments, a second groove 14 is further arranged within the first groove 13, and the through holes 130 extend to the second groove 14. In this embodiment, as shown in FIG. 7 and FIG. 8, the second groove 13 extends along the length direction of the first groove 13, and located within the first groove 13 between two pairs of positioning bodies 301.

At least part of the bottom surface of the first groove 13 protrudes from the lower surface of the baseplate 1, specifically, the bottom surface of the first groove 13 at the corresponding position to the second groove 14 protrudes from the lower surface of the baseplate 1, which can ensure the depth of the first groove 13 and the second groove 14 while preventing excessive thickness of the baseplate 1, achieving the goal of weight reduction.

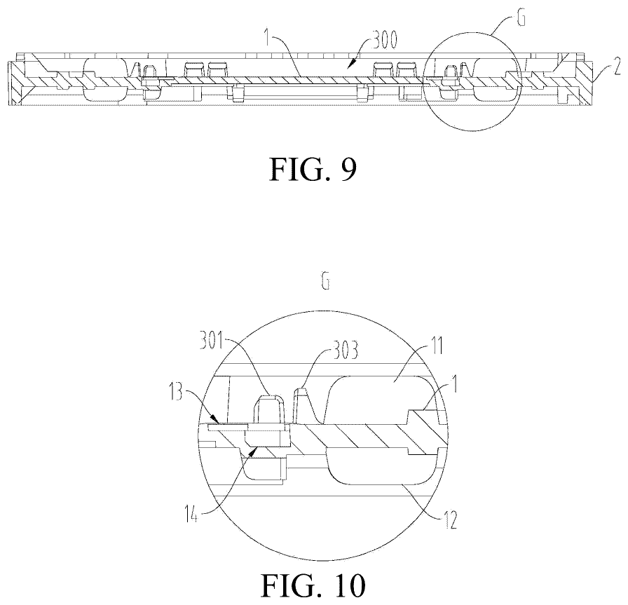

As shown in FIG. 8 to FIG. 10, the connecting body 303 is arranged on the upper surface of the baseplate 1, and extends along the thickness direction of the baseplate 1; the connecting body 303 is located on one side of the positioning body 301, and there is a gap between the connecting body 303 and the positioning body 301, and the connecting body 301 and the placement area 200 are located on two sides of the positioning body 301. In this embodiment, there are two connecting bodies 303 respectively arranged on side portions of two pairs of positioning bodies 301.

As shown in FIG. 2 and FIG. 6, the covering body 302 covers the surface of the positioning body 301 and the first groove 13, and passes through the through hole 130 and covers part of the lower surface of the baseplate 1. When the covering body 302 covers the positioning body 301, the covering body 302 penetrates the gap between the pair of convex columns of the positioning body 301, increasing the joint surface, at the same time, the covering body 302 covers the positioning body 301 completely, to provide more stable support. The portion of the covering body 302 covering the surface of the positioning body 301 has a supporting surface 3021 and a limiting surface 3022. The supporting surface 3021 can stably support the chip in the vertical direction, and the limiting surface 3022 extends in the vertical direction, and can limit the displacement of the chip in the horizontal direction. In this embodiment, an arrangement of multiple supporting surface 3021 is specifically provided.

In an implementation of this embodiment, the supporting surface 3021 extends in the horizontal direction (referring to the level when the tray is laid flat in the FIG.), that is, the supporting surface 3021 is a horizontal surface, and the height level of the supporting surface 3021 is higher than that of the upper surface of the baseplate 1, in this way, the perimeter of the chip can be supported on the horizontal supporting surface 3021 to ensure the stability of the support, as shown in FIG. 14.

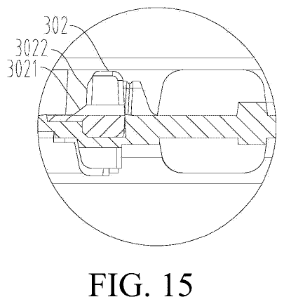

In another implementation of this embodiment, the supporting surface 3021 slops downwards to the placement area 300, that is, the supporting surface 3021 is an inclined face, and compared to a horizontal supporting surface 3021, the inclined supporting surface 3021 can minimize contact area with the welding spots on the chip and avoid damage, and the slope of the inclined surface may be adjusted to different angles according to the avoidance position at the bottom of the chip, as shown in FIG. 15.

In another implementation of this embodiment, the supporting surfaces 3021 on the surfaces of the positioning bodies 301 are independently arranged, with a total of eight positioning bodies 301, forming eight supporting surfaces 3021, in this way, stable support can be formed through two supporting surfaces 3021 in each of four directions, as shown in FIG. 1. Of course, the supporting surfaces 3021 may adopt a horizontal plane or an inclined plane mentioned above.

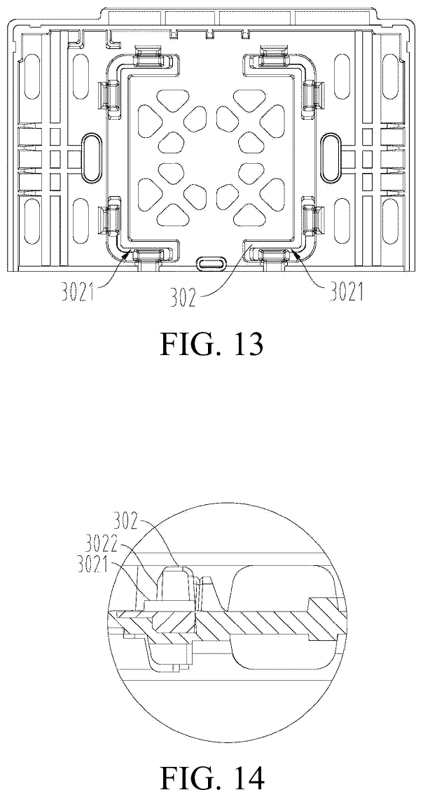

In another implementation of this embodiment, the supporting surfaces 3021 on the surfaces of two adjacent positioning bodies 301 in two adjacent directions are connected in an L-shape, that is, four L-shaped supporting surfaces 3021 are formed, in this way, it can form stable support at the corner positions, as shown in FIG. 13. Of course, the supporting surfaces 3021 may adopt a horizontal plane or an inclined plane mentioned above.

The height level of the covering body 302 covering the first groove 13 is slightly lower than the upper surface of the baseplate 1, that is, the covering body 302 will not protrude from the upper surface of the baseplate 1, and the upper surface of the baseplate 1 is 0.1-0.15 mm higher than the surface of the covering body 302, enclosing the covering body 302 to prevent flash. Due to the presence of a second groove 14 within the first groove 13, the covering body 302 also covers the second groove 14, and the second groove 14 is used to increase the contact area of the covering body 302, further improving its connection strength, of course, additional grooves may be further provided within the second groove 14 to further increase the contact area of the covering body 302.

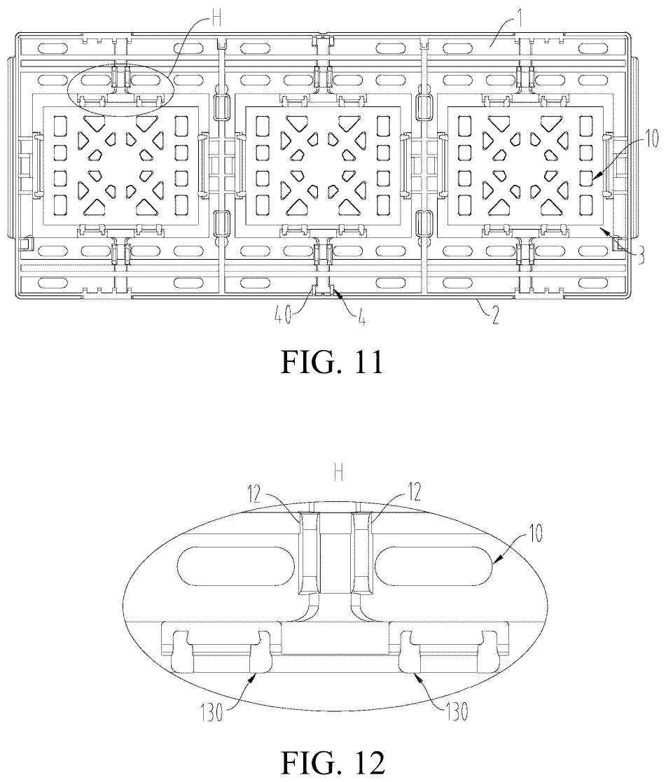

As shown in FIG. 11 and FIG. 12, after covering the first groove 13 and the second groove 14, the covering body 302 also passes through the through hole 130 and covers the lower surface of the baseplate 1 located at the edge of the through hole 130, that is, the size of the part of the covering body 302 extending from the through hole 130 is slightly larger than that of the through hole 130, forming an inversed buckle structure that firmly buckles the covering body 302, increases the bonding force with the covering body 302, further improves the connection stability, prevents the covering body 302 from falling off, and meanwhile saves the amount of material used for the covering body 302. In addition, the part of the covering body 302 extending from the through hole 130 has a guiding surface 3023, which extends obliquely in the up-down direction, that is, the guiding surface 3023 has an inverted cone shape, and the guiding surface 3023 can play a certain guiding role.

The covering body 302 also covers the space between the connecting body 303 and the positioning body 301, and by covering the space, the connection strength with the covering body 302 can be further improved.

In addition, the inner wall of the first groove 13, the inner wall of the second groove 14, the inner wall of the through hole 130, the surface of the positioning body 301, and the surface of the connecting body 303 can all be provided as rough and grainy walls, which can enhance the friction between them and the covering body 302 and further improve the connection strength with the covering body 302. Especially for the positions where the inner wall of the first groove 13 and the inner wall of the second groove 14 are combined with the covering body 302, a polished mirror surface treatment is applied, with a surface roughness of Ra 0.008 μm-Ra 0.016 μm, reducing the flow resistance of the covering body 302 in the mold, allowing it to be fully filled, and the covering body 302 to firmly adhere to the inner wall of the first groove 13 and the inner wall of the second groove 14.

The covering body 302 of the positioning unit 3 and the baseplate 1 are integrally formed by double-shot injection molding, with easy size control, short molding time, simple process, and high connection strength between the baseplate 1 and the covering bodies 302.

The baseplate 1, the frame 2, the positioning bodies 301 and the connecting bodies 303 of the positioning unit 3, and the reinforcing assembly 4 have the same material, and they can all use hard plastic, which mainly includes MPPO, PAS, PPE, ABS, etc.; the baseplate 1, the frame 2, the positioning bodies 301 and the connecting bodies 303 of the positioning unit 3, and the reinforcing assembly 4 are firstly injection molded to ensure the overall strength of the tray.

The material of the covering bodies 302 of the positioning unit 3 is an elastic material, such as soft plastic, which mainly includes TPU, TPE, silicone, etc., preferably TPU, which has good wear resistance, can be reused repeatedly, and without debris fall off.

After the baseplate 1 is formed, the covering bodies 302 are then formed on the positioning bodies 301, the first groove 13, and part of the baseplate 1 through injection molding to complete the final tray. The demolding angle of the mold is selected to 5°-8°; the mold temperature is controlled at 20 to 40° C. and water circulation is used; the surface roughness of the mold is Ra 25-35 μm, which reduces the demolding force and ensures the bonding strength between the covering bodies 302 and the positioning bodies 301, the first groove 13, and part of the baseplate 1.

In addition, due to the inverted buckle fit between the positioning assemblies 30 and the covering bodies 302, during the injection molding, the hard and soft plastic can adsorb and melt with each other to a certain extent, generating adhesive force and resulting in better connection strength between the covering bodies 302 formed on the positioning bodies 301 and the baseplate 1, without the need for adhesive bonding.

The embodiments described above are only for illustrating the technical concepts and features of the present disclosure, and are intended to make a person familiar with the technology being able to understand the content of the present disclosure and thereby implement it, and should not limit the protective scope of this disclosure.

1. A tray, comprising a baseplate (1), characterized in that, a positioning unit (3) for supporting a product is arranged on the baseplate (1), the positioning unit (3) comprises a plurality of positioning assemblies (30) distributed on an upper surface of the baseplate (1) and enclosing a placement area (300) therebetween; a first groove (13) is arranged on the upper surface of the baseplate (1), and a through hole (130) is opened within the first groove (13); each of the plurality of positioning assemblies (30) comprises a positioning body (301) and a covering body (302), the positioning body (301) is arranged within the first groove (13), and the covering body (302) covers the first groove (13) and a surface of the positioning body (301), and the covering body (302) passes through the through hole (130) and covers a part of a lower surface of the baseplate (1).

2. A tray, comprising a baseplate (1), characterized in that, a positioning unit (3) for supporting a product is arranged on the baseplate (1), the positioning unit (3) comprises a plurality of positioning assemblies (30) distributed on an upper surface of the baseplate (1) and enclosing a placement area (300) therebetween; a through hole (130) is opened on the baseplate (1); the plurality of positioning assemblies (30) comprise a positioning body (301) and a covering body (302), the covering body (302) covers a surface of the positioning body (301), and the covering body (302) passes through the through hole (130) and covers a part of a lower surface of the baseplate (1).

3. A tray, comprising a baseplate (1), characterized in that, a positioning unit (3) for supporting a product is arranged on the baseplate (1), the positioning unit (3) comprises a plurality of positioning assemblies (30) distributed on an upper surface of the baseplate (1) and enclosing a placement area (300) therebetween; a through hole (130) is opened on the baseplate (1); the plurality of positioning assemblies (30) comprise a covering body (302), and the covering body (302) passes through the through hole (130).

4. The tray as claimed in claim 1 is characterized in that, the baseplate (1) and the positioning body (301) are made of same material and integrally formed, the material of the baseplate (1) and the positioning body is selected from one of MPPO, PAS, PPE, and ABS.

5. The tray as claimed in claim 1, is characterized in that, the baseplate (1) and the covering body (302) are integrally formed by double-shot molding.

6. The tray as claimed in claim 1 is characterized in that, a material of the covering body (302) is an elastic plastic, the material of the covering body (302) is selected from one of TPU, TPE, and silicone.

7. The tray as claimed in claim 1, is characterized in that, a portion of the covering body (302) covering a surface of the positioning body (301) has a supporting surface (3021) for supporting the product in a vertical direction;
the supporting surface (3021) extends in a horizontal direction, and a height level of the supporting surface (3021) is higher than that of the upper surface of the baseplate (1); or, the supporting surface (3021) slops downwards to the placement area (300); or
supporting surface (3021) on each positioning body (301) is independently arranged; or
supporting surfaces (3021) of two adjacent positioning bodies (301) in two adjacent directions are connected in an L-shape.

8. The tray as claimed in claim 1, is characterized in that, a portion of the covering body (302) covering the surface of the positioning body (301) has a limiting surface (3022) extending in a vertical direction for limiting a displacement of the product in a horizontal direction.

9. The tray as claimed in claim 1, is characterized in that, a height level of the covering body (302) covering the first groove (13) is lower than that of the upper surface of the baseplate (1).

10. The tray as claimed in claim 1 is characterized in that, a portion of the covering body (302) extending out from the through hole (130) has a size larger than a size of the through hole (130), and form an inversed buckle structure.

11. The tray as claimed in claim 1, is characterized in that, each of the plurality of positioning assemblies (30) further comprises a connecting body (303) arranged on the upper surface of the baseplate (1) on a side of the positioning body (301), the connecting body (303) and the placement area (300) are respectively located on two sides of the positioning body (301), and the covering body (302) covers a space between the connecting body (303) and the positioning body (301).

12. The tray as claimed in claim 1, is characterized in that, a second groove (14) is further arranged within the first groove (13), and the through hole (130) extends to the second groove (14).

13. The tray as claimed in claim 1, is characterized in that, at least part of a bottom surface of the first groove (13) protrudes from a lower surface of the baseplate (1); or
the plurality of positioning assemblies (30) enclose the placement area (300) in a square shape; or
a plurality of positioning bodies (301) are arranged along a length direction of the first groove (13); a width of a top of each of the plurality of positioning bodies (301) is less than a width of a bottom thereof; or
a plurality of through holes (130) are arranged along a length direction of the first groove (13).

14. The tray as claimed in claim 1, is characterized in that, an upper supporting body (11) is arranged on the upper surface of the baseplate (1), and when multiple trays are stacked, the upper supporting body (11) of one tray located at a lower layer supports the lower surface of another tray located at an upper layer.

15. The tray as claimed in claim 12, is characterized in that, a lower supporting body (12) is arranged on the lower surface of the baseplate (1), and when multiple trays are stacked, the upper supporting body (11) of one tray located at a lower layer supports the lower supporting body (12) of another tray located at an upper layer.

16. The tray as claimed in claim 1, is characterized in that, a plurality of lightening holes (10) penetrate through the baseplate (1) are arranged on the baseplate (1); or
the tray further comprises a frame (2) enclosing a perimeter of the baseplate (1), the frame (2) protrudes from both the upper surface and the lower surface of the baseplate (1), to form an enclosure around it; when multiple trays are stacked, frames (2) of two adjacent trays abut each other, the tray further comprises a reinforcing assembly (4) comprising a reinforcing rib (40) arranged between the baseplate (1) and the frame (2); or
a plurality of positioning units (3) are distributed along a length direction of the baseplate (1).

17. A positioning unit, comprising□
a plurality of positioning assemblies, distributed on an upper surface of the baseplate and enclosing a placement area therebetween;
wherein, the plurality of positioning assemblies are arranged on a baseplate, each of the plurality of positioning assemblies comprises a positioning body covering an upper surface of the baseplate;
a through hole is opened on the baseplate, the covering body passes through the through hole and covers a part of a lower surface of the baseplate, a material of the covering body is elastic.

18. The positioning unit of claim 1, wherein, a portion of the covering body covering a surface of the positioning body has a supporting surface for supporting the product in a vertical direction.

19. The positioning unit of claim 1, wherein, a portion of the covering body extending out from the through hole has a size larger than a size of the through hole, and form an inversed buckle structure; and/or
a portion of the covering body extending out of the through hole has a guiding surface, and the guiding surface extends obliquely in a vertical direction and is in an inverted cone shape.
